(19) United States
(12) Patent Application Publication
(10) Pub. No.: US 2017/0133499 A1
(43) Pub. Date: May 11, 2017

(54) HIGH ELECTRON-MOBILITY TRANSISTOR PRIMARILY MADE OF NITRIDE SEMICONDUCTOR MATERIALS

(71) Applicant: Sumitomo Electric Industries, Ltd., Osaka-shi (JP)

(72) Inventor: Chihoko Mizue, Yokohama-shi (JP)

(21) Appl. No.: 15/348,076

(22) Filed: Nov. 10, 2016

(30) Foreign Application Priority Data
Nov. 11, 2015 (JP) 2015-221376

(51) Int. Cl. H01L 29/778; H01L 29/417; H01L 29/51

(52) U.S. Cl. CPC H01L 29/7787; H01L 29/517; H01L 29/41758; H01L 29/511

(57) ABSTRACT

A high electron-mobility transistor (HEMT) is disclosed. The HEMT includes a channel, a barrier, and a cap layers each made of nitride semiconductor materials. The HEMT further provides, on the cap layer, a couple of insulating films of a first film made of one of SiN and SiON with a silicon rich composition and a thickness of 10 to 50 nm, and second film made of one of AlO, AlN, SiO, AlON with a oxide or nitride rich composition and a thickness of 20 to 100 nm.

### BACKGROUND OF THE INVENTION

1. Field of the Invention

The present invention relates to a semiconductor device, in particular, the invention relates to a nitride semiconductor device.

2. Background Arts

A nitride semiconductor device, in particular, a high electron-mobility transistor (HEMT) made of gallium nitride (GaN) and other nitride semiconductor materials has become popular especially in a field of requesting higher power and high breakdown voltage. However, a HEMT made of GaN and other materials inherently shows a decrease of a drain current after a large drain current is turned off, which is usually called as the current collapsing. A HEMT disclosed in a Japanese Patent application laid open No. JP2014-078537 provides an insulating film that covers a surface of the nitride semiconductor layer exposed between the gate electrode and the drain electrode.

### SUMMARY OF THE INVENTION

One aspect of the present invention relates to a high electron-mobility transistor (HEMT) primarily made of nitride semiconductor materials. The HEMT includes a channel layer, a barrier layer, a first insulating film and a second insulating film. The channel layer may be made of nitride semiconductor material. The barrier layer may be also made of nitride semiconductor material but has an electron affinity smaller than that of the channel layer. The first insulating film, which is provided on the barrier layer, may be made of one of silicon nitride (SiN) and silicon oxy-nitride (SiON) with a thickness not thinner than 10 nm but not thicker than 50 nm. The second insulating film, which is provided on the first insulating film, is made of one of aluminum oxide (AlO), aluminum nitride (AlN), silicon oxide (SiO), aluminum oxy-nitride (AlON with a thickness of not thinner than 20 nm but not thicker than 100 nm.

Another aspect of the present invention also relates to a HEMT primarily made of nitride semiconductor materials. The HEMT includes a channel layer made of nitride semiconductor material, a barrier layer also made of nitride semiconductor materials, a first insulating film, and a second insulating film. The first insulating film, which is provided on the barrier layer, may be made of silicon nitride (SiN) with a silicon rich composition compared with a native silicon nitride with a composition of Si₃N₄. The second insulating film, which is provided on the first insulating film, is made of aluminum oxide (AlO) with an aluminum rich composition compared with a native aluminum oxide with a composition of Al₂O₃.

### DESCRIPTION OF DRAWINGS

The accompanying drawings, which are incorporated in and constitute a part of this specification, illustrate one or more implementations described herein and, together with the description, explain these implementations. In the drawings:

FIG. 1 schematically illustrates a cross section of a semiconductor device according to the first embodiment of the present invention;

FIGS. 2A to 2C show processes of forming the semiconductor device of the first embodiment;

FIGS. 3A and 3B show processes of forming the semiconductor device of the first embodiment;

FIG. 4 schematically illustrates a cross section of a semiconductor device comparable to the present invention;

FIG. 5 schematically shows a band diagram of the semiconductor device comparable to the present invention;

FIG. 6 schematically shows a band diagram of the semiconductor device of the first embodiment of the present invention;

FIG. 7 schematically illustrates a cross section of a semiconductor device according to the second embodiment of the present invention;

FIGS. 8A to 8C show processes of forming the semiconductor device of the second embodiment shown in FIG. 7;

FIGS. 9A to 9C show processes of forming the semiconductor device of the second embodiment, where the processes are subsequent to the processes shown in FIGS. 8A to 8C;

FIG. 10 schematically shows a cross section of the semiconductor device according to the second embodiment of the present invention;

FIGS. 11A and 11B show processes of forming the semiconductor device of the second embodiment, where the processes are modified from those shown in FIGS. 8A to 9C; and

FIG. 12A evaluates the current collapse of the semiconductor device comparable to the present invention, and FIG. 12B evaluates the current collapse of the semiconductor device of the present invention.

### DESCRIPTION OF EMBODIMENT

Next, embodiment according to the present invention will be described as referring to drawings. In the description of the drawings, numerals or symbols same with or similar to each other will refer to elements same with or similar to each other without duplicating explanations.

### First Embodiment

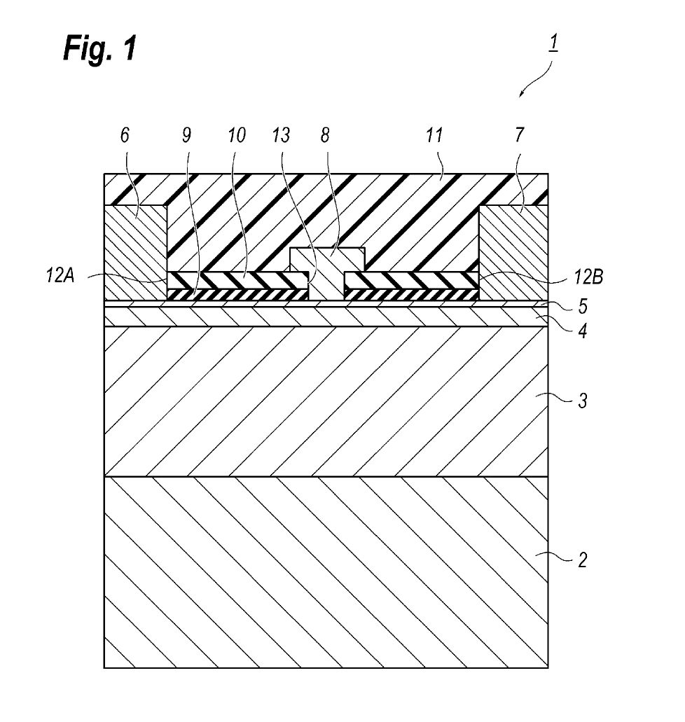

FIG. 1 schematically illustrates a cross section of a semiconductor device 1 according to the first embodiment of the present invention. The semiconductor device 1, which is a type of field effect transistor (FET), or sometimes called as a high electron-mobility transistor (HEMT), includes a substrate 2, a channel layer 3, a barrier layer 4, a cap layer 5, electrodes of a source 6, a drain 7, and a gate 8, a silicon nitride (SiN) layer 9 as the first insulating film, and an aluminum oxide (AlO) layer 10 as the second insulating film. The HEMT 1 may be covered with a passivation layer 11, which may be made of resin, silicon nitride (SiN), and so on, as the third insulating film. The barrier layer 4, which has the electron affinity smaller than the electron affinity of the channel layer 3, forms two-dimensional electron gas (2DEG) in the channel layer 2 adjacent to an interface against the barrier layer 3, which becomes the channel of the HEMT 1.

The substrate 2, which may be made of silicon (Si), silicon carbide (SiC), sapphire (Al₂O₃), and/or diamond, is prepared for epitaxially growing semiconductor layers, 3 to 5, thereon. The present HEMT 1 provides the substrate made of silicon carbide (SiC). The channel layer 3, which is epitaxially grown on the substrate 2, may be made of nitride semiconductor materials having a thickness of 300 to 1600 nm. The HEMT 1 of the present embodiment provides the channel layer 3 made of gallium nitride (GaN).

The barrier layer 4, which is epitaxially grown on the channel layer 3, may be made of nitride semiconductor materials having electron affinity smaller than that of the channel layer. The battier layer 4 is made of, for instance, aluminum gallium nitride (AlGaN), indium aluminum nitride (InAlN), indium aluminum gallium nitride (InAlGaN), and so on. The present embodiment provides the barrier layer 4 made of AlGaN with a thickness thicker than or equal to 10 nm but thinner than or equal to 30 nm. The cap layer 5, which is grown on the barrier layer 4, may be also made of nitride semiconductor materials, for instance, gallium nitride (GaN). The present HEMT 1 has the cap layer 5 made of GaN with a thickness of 1 to 10 nm.

A source electrode 6 and a drain electrode 7, where they are provided on the cap layer 5, make non-rectifying contact to the cap layer 5 and have a stacked arrangement of titanium (Ti) in contact to the cap layer 5 and aluminum (Al) on the titanium. In an alternative, the aluminum (Al) may be sandwiched between titanium (Ti), that is, other titanium (Ti) may be provided on the aluminum (Al). The gate electrode 8, which I also in contact to the cap layer 5, is put between the source electrode 6 and the drain electrode 7. The gate electrode 8 may have a stacked arrangement of nickel (Ni), platinum (Pt), and gold (Au), where nickel (Ni) is in contact to the cap layer 5.

The SiN film 9, which is provided on the cap layer 5, is an electrically insulating film. The SiN film 9 of the present embodiment, exactly, the SixNy film 9, has a ratio of a composition y of nitrogen (N) to the composition x of silicon (Si), namely the ratio y/x, greater than or equal to 3/17 but less than or equal to 4/3, 3/17<=y/x<=4/3. The SiN film 9 of the present embodiment has the silicon rich composition compared with that of a native SiN film whose composition is given by Si₃N₄. The SiN film 9 having silicon rich composition may lower an insulating characteristic thereof, which may affect the band diagram in the barrier layer 4 described later in the specification. Also, the composition ratio (y/x) described above greater than 3/17 in the SiN film 9 may effectively suppress leak currents flowing therethrough.

The SiN film 9 may have a thickness not thinner than 10 nm but not thicker than 200 nm, preferably less than 100 nm, or further preferably less than 50 nm. When the SiN film 9 has the composition ratio y/x above described and the thickness of 10 to 200 nm, the SiN film 9 may effectively affect or influence the band diagram in the barrier layer 4. A minimum thickness of 10 nm of the SiN film 9 may be decided from process stability, or process reproducibility of forming the HEMT 1

The aluminum oxide (AlO) film 10, which is provided on the SiN film 9, sandwiches the gate electrode 8 therebetween and is in contact thereto. The AlO film 10 has bandgap energy greater than that of the SiN film 9, which means that the AlO film 10 has an insulating performance higher than that of the SiN film 9. The AlO film 10 of the present embodiment has a composition y of oxygen (O) against that x of aluminum (Al), namely, y/x, greater than 3/2 but not greater than 3, 3/2<y/x<=3, which means that the AlO film 10 of the present embodiment has the oxygen rich composition compared with a native aluminum oxide (Al₂O₃). An AlO film with oxygen composition greater than 3/2 may be easily formed compared with an AlO film having oxygen composition smaller than the ordinary composition. Such an AlO film with the oxygen rich composition may raise the band diagram of the barrier layer 4 at the interface against the SiN film 9. The AlO film 10 preferably has a thickness not thinner than 10 nm but not thicker than 600 nm. When a designed thickness of an AlO film is not thinner than 10 nm, such an AlO film may be formed stably and reproducibly. When a designed thickness of an AlO film is not thicker than 600 nm, such an AlO film may be formed in a short time. An AlO film with a thickness of 10 to 600 nm and oxygen rich composition may raise the band diagram of the barrier layer 4 at the interface against the SiN film 9.

The SiN film 9 and the AlO film 10 cover and protect the semiconductor stack of the cap layer 5, the barrier layer 4, and the channel layer 3. The SiN film 9 and the AlO film 10 provide openings, 12A, 12B, and 13, corresponding to the source electrode 6, the drain electrode 7, and the gate electrode 8. These electrodes, 6 to 8, are directly in contact to the cap layer 5 as piercing the respective openings, 12A to 13.

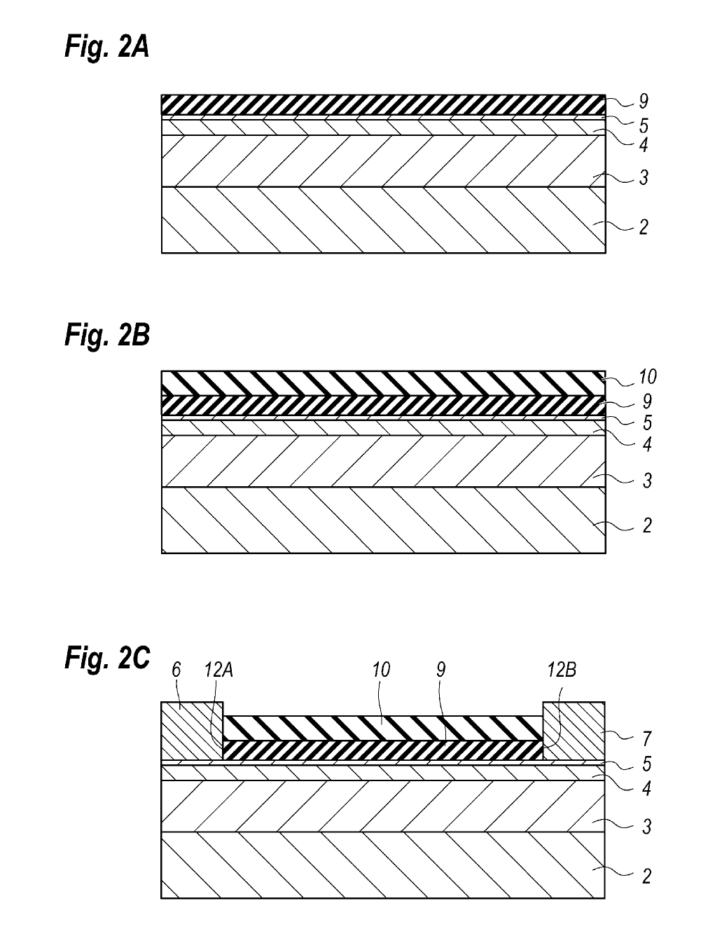

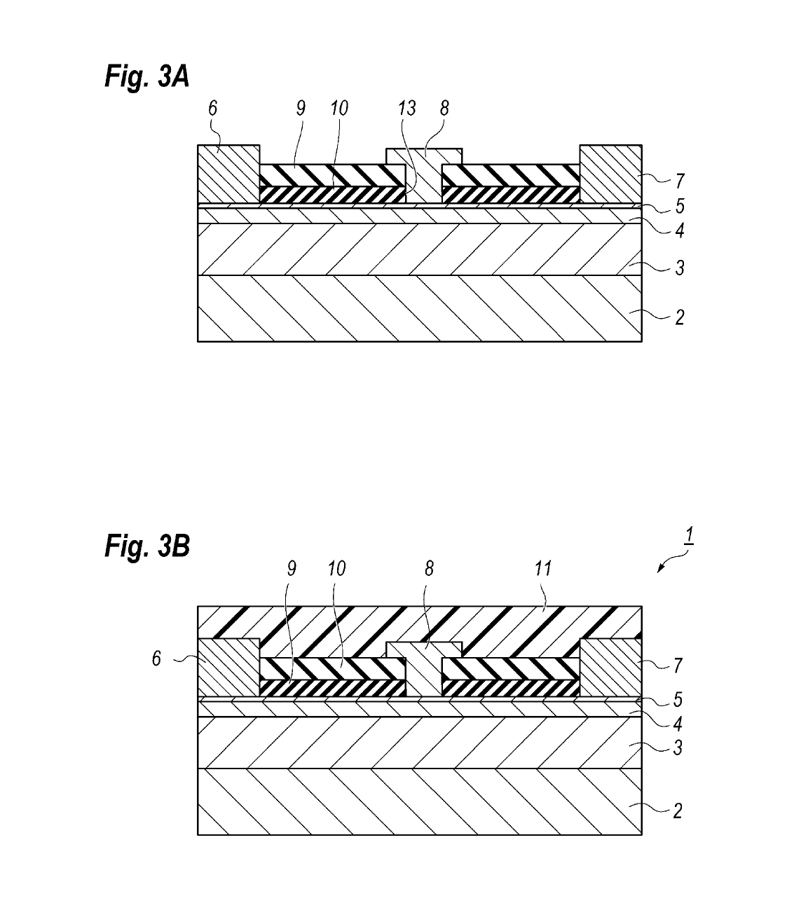

Next, a process of making a HEMT 1 according to the first embodiment of the present invention will be described, as referring to FIGS. 2A to 3B that show cross section of the HEMT 1 at the respective processes.

First, as FIG. 2A illustrates, the process deposits the SiN film 9 by a thickness of 20 nm on a semiconductor stack that includes, on the substrate 2, the channel layer 3, the barrier layer 4, and the cap layer 5 each sequentially grown by, for instance, the chemical vapor deposition (CVD) technique. The SiN film 9 has the composition ratio of nitrogen (N) against silicon (Si), N/Si, not smaller than 3/17 but not greater than 4/3, namely, silicon rich composition compared to a native SiN film that has the composition of Si₃N₄.

The substrate 2 in the present embodiment is made of silicon carbide (SiC). The channel layer 3, the barrier layer 4, and the cap payer 5 are sequentially and epitaxially grown on the substrate 2 by, for instance, the metal organic chemical vapor deposition (MOCVD) technique. The barrier layer 4 of the embodiment may be made of AlGaN with an aluminum (Al) composition of 25%, namely, Al_{0.25}Ga_{0.75}N, and a thickness of 20 nm. The cap layer 5 may be made of gallium nitride (GaN) with a thickness of 2 nm. The channel layer 3 may be made of also gallium nitride (GaN). The channel layer 3 may be heat treated before the growth of the barrier layer 4 thereon.

In advance to the deposition of the AlO film 10, the substrate accompanied with those semiconductor layers, 3 to 5, and the SiN film 9 are dipped within an organic solvent to remove dusts, particles, and/or, contamination left on the SiN film 9. For instance, the process may carry out the ultrasonic cleaning by dipping the substrate 2 with the SiN film 9 within acetone and further dipping within ethanol as providing the ultrasonic waves within the organic solvent.

Then, as FIG. 2B illustrates, the process forms an AlO film 10 by a thickness of 40 nm on the SiN film 9 by, for instance, the atomic layer deposition (ALD) technique. The AlO film 10 thus deposited has the composition of oxygen (O) against aluminum (Al), namely, O/Al, greater than 3/2 but smaller than 3. That is, the AlO film 10 of the embodiment has oxygen rich composition compared to a native AlO film that has the composition of Al₂O₃. The ALD technique of the present embodiment supplies ozone (O₃), which is one of oxidizing agents, within an apparatus of the ALD technique during the formation of the AlO film 10, which may enhance the deposition of the AlO film 10 with an oxygen rich composition on the SiN film 9.

Then, as FIG. 2C illustrates, the process forms openings, 12A and 12B, in the AlO film 10 and the SiN film 9 sequentially, and further forms a source electrode 6 and a drain electrode 7 within the openings, 12A and 12B. A reactive ion etching (RIE) using boron tri-chloride (BCl₃) as a reactive gas, or a wet-etching using fluoric acid (HF) may form the openings, 12A and 12B. Heat treatment of metals deposited within openings, 12A and 12B, may form un-rectified contact to the semiconductor layer. The heat treatment at a temperature of 850 to 950° C. for one to five minutes under an atmosphere of an inert gas, for instance, nitrogen (N), argon (Ar), or else may form the non-rectifying contact for the source and drain electrodes.

Then, as FIG. 3A illustrates, forming an opening 13 in the AlO film 10 and in the SiN film 9 sequentially and exposing the surface of the cap layer 5; the process forms the gate electrode 8 within the opening 13 so as to be directly in contact to the cap layer 5. Specifically, the process first forms a patterned photoresist that has openings for the opening 13 is first deposited on the AlO film 10, then etches the AlO film 10 and the SiN film 9 sequentially to form the opening 13, and finally deposit a stacked metal of nickel (Ni) and gold (Au) within the opening 13. Thus, the gate electrode 13 is formed.

Then, the another insulating film 11 covers the electrodes, 6 to 8, and the AlO film 10 between the electrodes, 6 to 8, as shown in FIG. 3B Thus, the HEMT 1 of the present embodiment is completed.

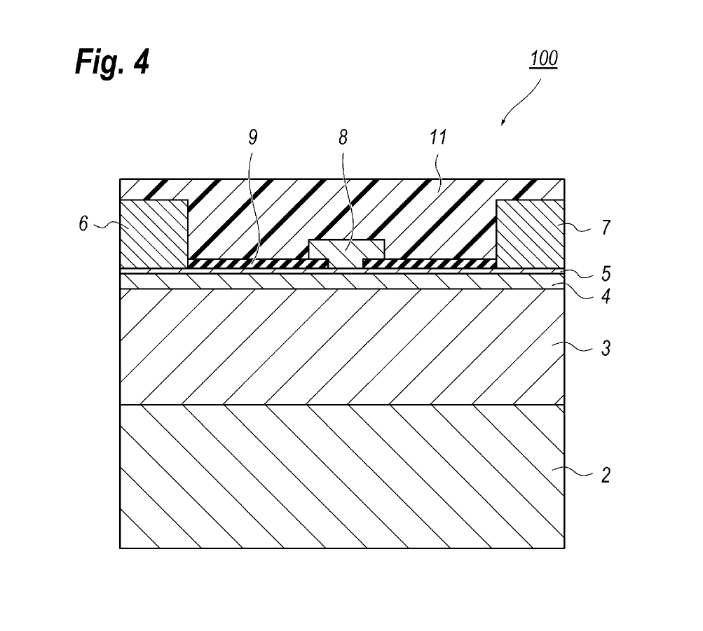

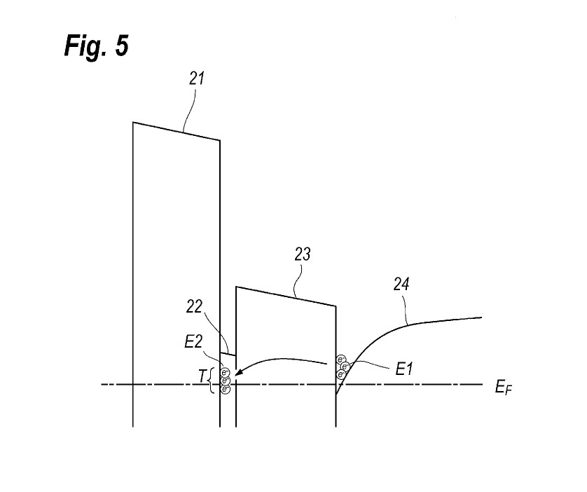

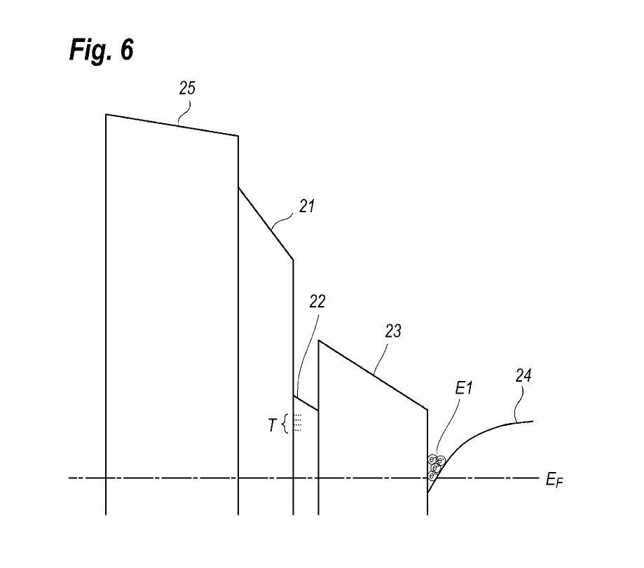

Next, advantages of the HEMT formed by the process of the first embodiment will be described as referring to FIGS. 4 to 6, where FIG. 4 shows a cross section of a HEMT comparable to the HEMT 1 of the present invention, FIG. 5 schematically illustrates the energy diagram of the comparable HEMT shown in FIG. 5, and FIG. 6 schematically illustrates the energy diagram of the HEMT 1 of the invention. The comparable HEMT 100 shown in FIG. 4 has arrangements substantially same with those of the HEMT 1 of the invention except that the comparable HEMT 100 does not provide the AlO film 10 on the SiN film 9. Such HEMT 100 provides the energy diagram shown in FIG. 5. In FIGS. 5 and 6, elements, 21 to 25, correspond to the energy diagram of the SiN film 9, the cap layer 5, the barrier layer 4, the channel layer 3, and the AlO film 10, respectively.

As FIG. 5 indicates, the comparable HEMT 100 provides the channel in the channel layer 24, exactly, the channel layer 24 at the interface against the barrier layer 23, within which carriers, or electrons E 1 flow therein. A portion of the electrons E 1 hops the barrier layer 23 accelerated or energized by the bias between the drain and the source and fall into surface states inherently existing in the surface of the cap layer 22. Some of the surface states behave as electron traps T which electrifies the surface of the cap layer 22 in negative when the electrons are captured, and the negatively electrified traps partially depletes the channel; accordingly, the drain current reduces. The capture of the electrons by the traps T depends on a difference of the energy level of the traps T against the Fermi level E_{F}.

The energy level of the traps T is slightly higher than the Fermi level E_{F} even when the SiN film 21 provided in the surface of the cap layer 22 raises the energy level of the cap layer at the interface thereto. Under such a condition, when the HEMT 100 is normally biased, which raises the Fermi level E_{F} in the channel layer 24; the energy level of the traps T becomes comparable or sometimes lower than the level of the cannel in the channel layer 24. Thus, in the system having only the SiN film 21, substantial electrons in the channel are captured in the traps T existing in the surface of the cap layer 22 under the normal bias condition, which electrifies the surface of the cap layer 22 negative and decreases the drain current at the subsequent operation of the HEMT 100.

On the other hand, the HEMT 1 of the embodiment, as shown in FIG. 6, provides a double layers of the SiN film 21 and the AlO film 25 on the cap layer 22. Because aluminum oxide has the work function smaller than that of silicon nitride 21; the AlO film 25 may raise the energy band of the SiN film 21 at the interface therebetween when two materials are continuously formed, and the band diagram from the AlO film 25 to the channel layer 24 becomes those shown in FIG. 6. The AlO film 25 raises the band of the SiN film 21 at the interface therebetween, and the SiN film 21 raises the band of the cap layer 22 and the barrier layer 23. Because the AlO film 25 shows resistivity smaller than that of the SiN film 21, the bands in slopes thereof becomes moderate in the AlO film 25 but becomes steep in the SiN film 21 and the semiconductor layers, 22 and 23. Accordingly, because the band of the cap layer 22 is raised at the interface against the SiN film 21 compared with the system without the AlO film 25 shown in FIG. 5, the energy level of the traps in a difference against the Fermi level E_{F} becomes larger, which reduces the possibility for the electrons E 1 in the channel to be captured in the traps. The possibility of the capture of the electrons E 1 exponentially depends on the difference between the energy levels, accordingly, even a slight increase of the energy level of the traps T measured from the Fermi level E_{F}, the capture of the electrons E 1 by the traps T drastically decreases.

In a system where a HEMT only provides the AlO film, that is, the AlO film is directly in contact to the cap layer without interposing the SiN film; the AlO film may not raise the energy level of the cap layer at the interface against the AlO film as that raised by the SiN film, the traps T in the energy level thereof becomes not so high measured from the Fermi level E_{F}. Accordingly, the capture of the electrons in the channel likely occurs and the subsequent drain current decrease.

The explanation above assumes that the cap layer 22 exists between the barrier layer 23 and the SiN film 21. However, another arrangement when the SiN film 21 is provided directly on the barrier layer 23, that is, the cap layer 22 is removed from the arrangement; explanations above may be applicable because the surface states or the electron traps T are also inherently formed in the surface of the barrier layer 23 facing and in contact to the SiN film 21.

The SiN film 9 of the embodiment preferably has a thickness of 10 to 200 nm, where such a SiN film may effectively raise the energy band of the barrier layer 4 at the interface against the SiN film 9. The AlO film 10 preferably has a thickness of 20 to 100 nm. The AlO film 10 may cover the SiN film 9 and the electrodes, 7 to 8. The AlO film 10 may be in contact to the gate electrode 8. The electron traps in the surface of the cap layer 5, or the barrier layer 4, may capture the electrons not only in the channel but also those leaked from the gate electrode 8 to the drain electrode 7. That is, when the HEMT 1 receives a stress bias, namely a large positive gate bias concurrently with a large negative gate bias, which fully depletes the channel and causes a large negative bias between the gate electrode 8 and the drain electrode 9. Such a stress bias causes a substantial current leaked from the gate electrode 8 to the drain electrode 7 and may electrify the surface of the cap layer 5 or the barrier layer 4 by the traps T capturing the electrons. The capture of the electrons may likely occur near the gate electrode 8, exactly, in a side of the gate electrode 8 facing the drain electrode 7. The AlO film 10 fully covering the gate electrode 8 including the side of the drain electrode 7 may effectively reduce the possibility of the capture of the electrons.

The AlO film 10 may be formed in advance to the formation of the electrodes, 6 to 8. Such a process for the AlO film 10 may prevent failures or breakages of the AlO film 10 at steps formed in the SiN film 9 or the electrodes, 7 to 8. The AlO film 10 may be formed by the atomic layer deposition (ALD) technique.

### Second Embodiment

Next, a process of forming a HEMT according to the second embodiment of the present invention will be described. The description below omits explanations for elements same with those of the first embodiment. Elements different from those of the first embodiment will be explained.

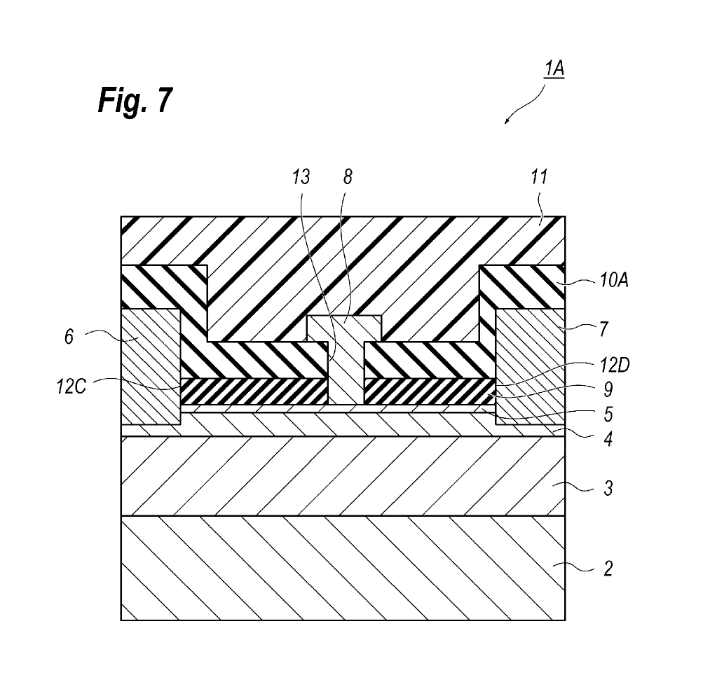

FIG. 7 shows a cross section of a HEMT according to the second embodiment of the present invention. The HEMT 1A shown in FIG. 7 provides, in addition to the SiN film 9, an AlO film 10A that covers the source electrode 6 and the drain electrode 7. The openings, 12C and 12D, for the source and drain electrodes, 6 and 7, which are not provided in the AlO film 10A, exposes the barrier layer 4. That is, the openings, 12C and 12D, pierce the SiN film 9 and the cap layer 5. Accordingly, the source and drain electrodes, 6 and 7, are directly in contact to the barrier layer 4 within the openings, 12C and 12D.

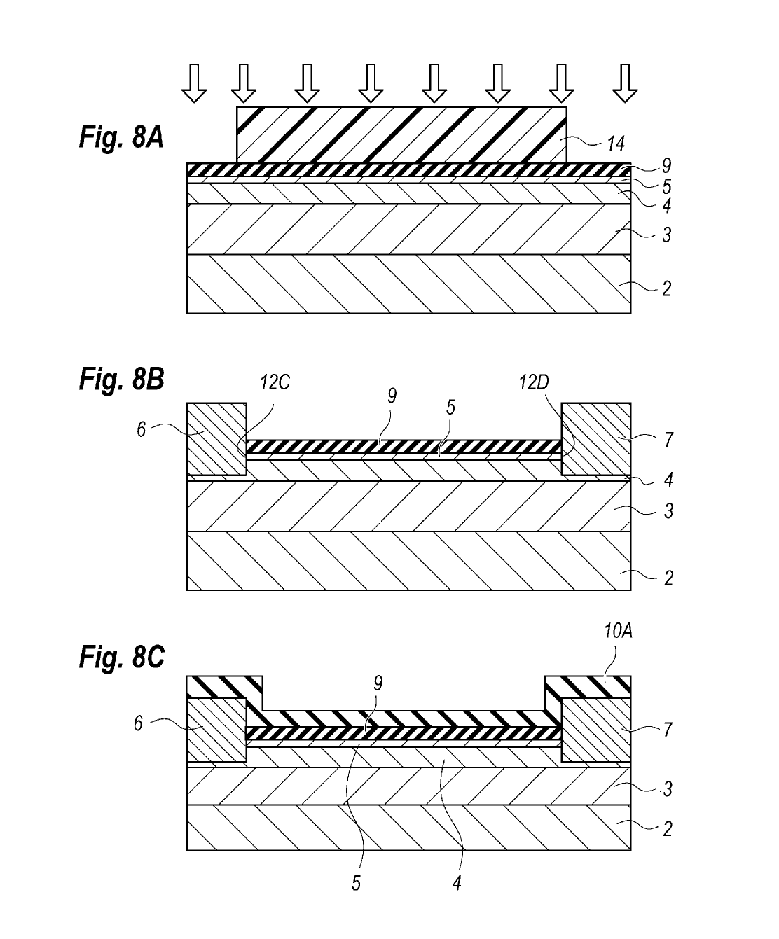

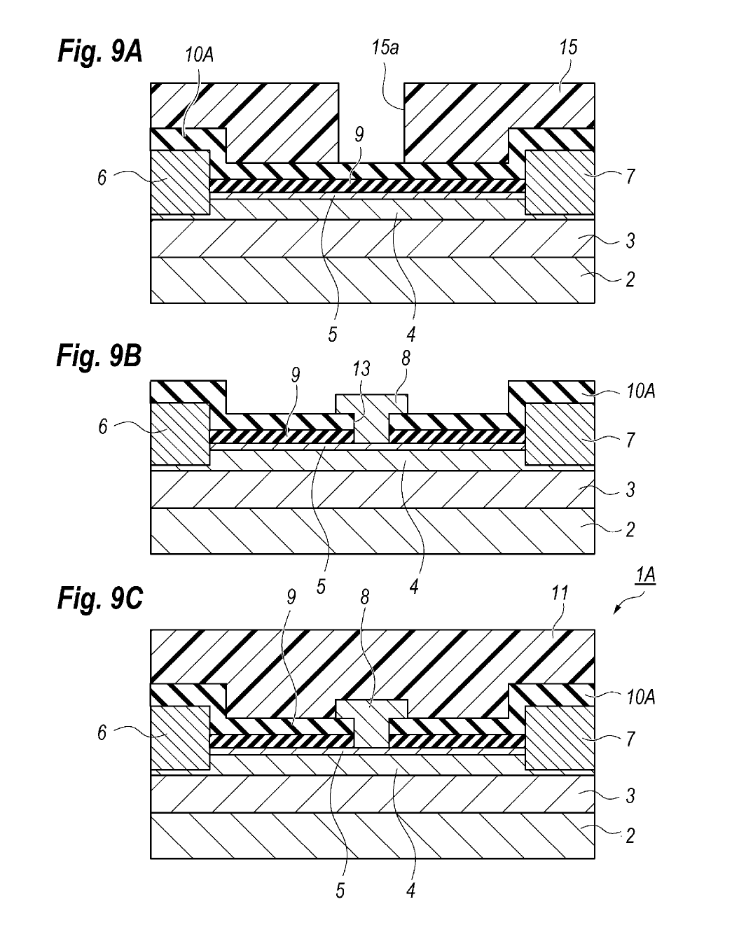

The process of forming the HEMT 1A will be next described as referring to FIGS. 8A to 9C, where those figures show the processes of forming the HEMT 1A.

First, as FIG. 8A indicates, the process forms a patterned photoresist 14, which may be a nega-type photoresist and a posi-type photoresist, on the SiN film 9 so as to cover a primary portion of the semiconductor layers, 3 to 5. Then, as FIG. 8B indicates, the process partially etches the SiN film 9, the cap layer 5, and the barrier layer 4 in portions exposed from the patterned photoresist 14 so as to form the openings, 12C and 12D. Then, the source electrode 6 and the drain electrode 7 are formed within the respective openings, 12C and 12D. The patterned photoresist may be removed before or after the formation of the electrodes, 6 and 7. After the formation of the electrodes, 6 and 7, or the removal of the patterned photoresist 14, the process carries out the cleaning of the surface of the SiN film 9 left between the electrodes 6 and 7, and the surface of the electrodes, 6 and 7, by an organic solvent.

Next, as FIG. 8C indicates, the process forms the AlO film 10A on the SiN film 9, the source electrode 6, and the drain electrode 7 by, for instance, the atomic layer deposition (ALD) technique with a thickness of greater than 40 nm. The AlO film 10A in the thickness thereof is secured so as to show a good coverage for steps of underlying layers.

Next, as FIG. 9A indicates, the process forms another patterned photoresist 15 on the AlO film 10A, where the patterned photoresist provides an opening 15a in a position corresponding to the gate electrode. The patterned photoresist 15 may be also a nega-type photoresist or a posi-type photoresist. Then, as FIG. 9B indicates, the process forms another opening 13 by sequentially etching the AlO film 10A and the SiN film 9 so as to expose the surface of the cap layer 5 in a bottom of the opening 13; and forms the gate electrode 8 by filling the opening 13 with the gate electrode 8. Finally, the passivation film 11 covers the whole surface of the AlO film 10A and the gate electrode 8. Thus, the HEMT 1A of the second embodiment is formed.

The HEMT 1A of the second embodiment may show advantages same with those attributed to the HEMT 1 of the first embodiment. In addition, the HEMT 1A of the second embodiment forms the AlO film 10A after the formation of the source electrode 6 and the drain electrode 7. That is, the AlO film 10A may be free from, or not influenced by the heat treatment carried out during the formation of the electrodes, 6 and 7, which may prevent the AlO film 10A from deterioration and reduce the leak current between electrodes, 6 to 8. Moreover, the AlO film 10A covering the source electrode 6 and the drain elector 7 may prevent the electrodes, 6 and 7, from deterioration. The deterioration of the AlO film 10A means that grain sizes of the AlO poly crystal becomes smaller.

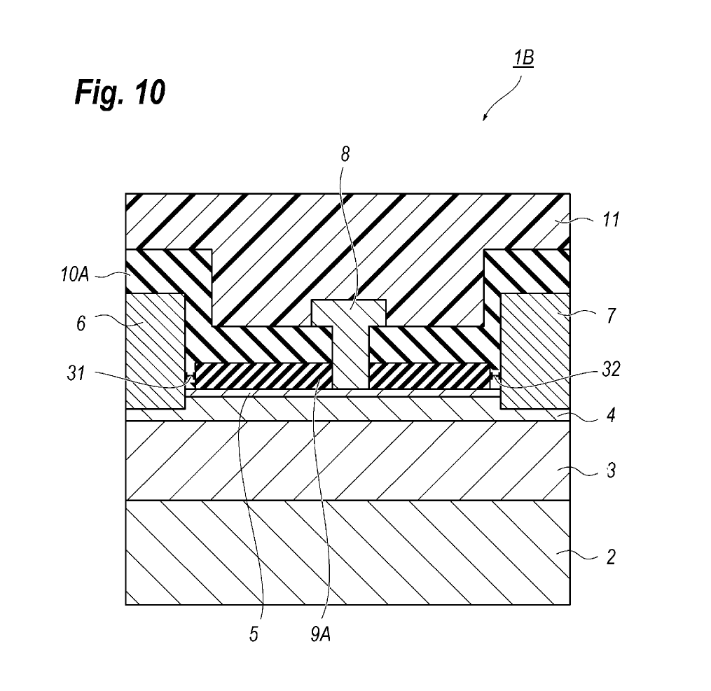

FIG. 10 shows a cross section of a HEMT 1B modified from the HEMT 1A of the second embodiment. The HEMT 1B provides the SiN film 9A, substituted from the SiN film 9 in the second embodiment, whose width is narrower than a distance between the source electrode 6 and the drain electrode 7. That is, gaps, 31 and 32, are left between the electrodes, 6 and 7, and the SiN film 9A, respectively. The AlO film 10A partially fills the gaps, 31 and 32, along the stacking direction of the semiconductor layers, 3 to 5. That is, the AlO film 10A is put between the source electrode 6 and the SiN film 9A, and between the drain electrode 7 and the SiN film 9A.

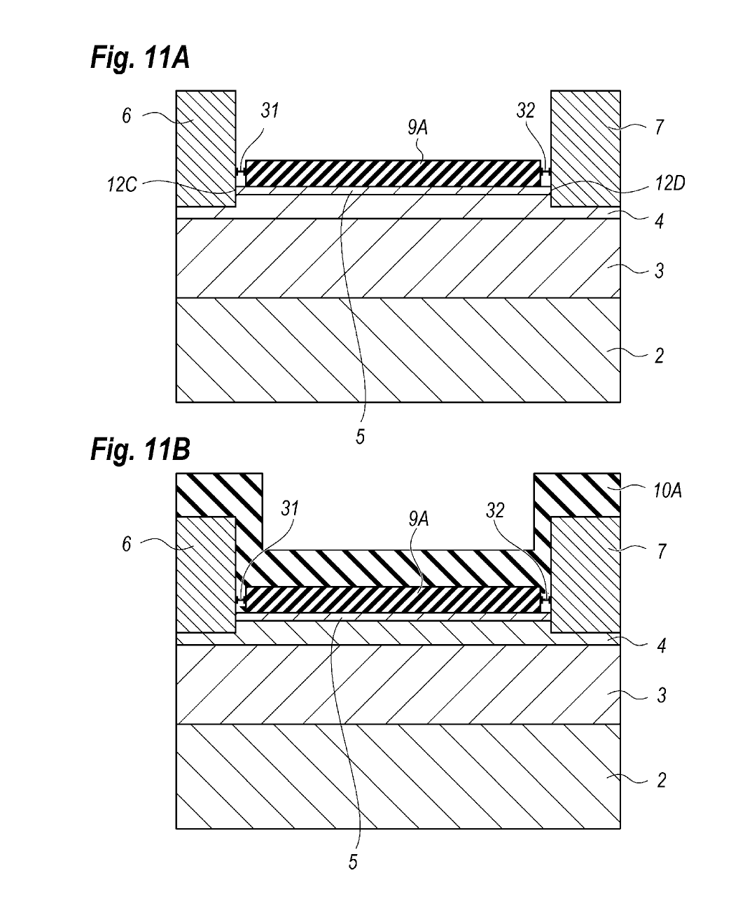

FIGS. 11A and 11B show processes of forming the HEMT 1B. As FIG. 11A indicates, the process may form the gaps, 31 and 32, at the formation of the electrodes, 6 and 7, within the respective openings, 12C and 12D. Specifically, when the SiN film 9A is partially etched in the regions corresponding to the openings, 12C and 12D, the SiN film 9A in edges facing the openings, 12C and 12D, are excessively etched so as to retreat from the edges of the patterned photoresist 14. Then, as FIG. 11B indicates, after the formation of the electrodes, 6 and 7, the AlO film 10A covers the electrodes, 6 and 7, and the SiN film 9A between the electrodes, 6 and 7, so as to partially fill the gaps, 31 and 32, between the electrodes, 6 and 7, and the SiN film 9A.

The HEMT 1B shown in FIG. 10 may show advantages substantially same with those appearing in the HEMT 1A of the second embodiment. In addition, the AlO film partially fills the gaps, 31 and 32, between the electrodes, 6 and 7, and the SiN film 9A may isolate the electrodes, 6 and 7, from the SiN film 9A. Accordingly, the formation of the electrodes, 6 and 7, may not accompany with the formation of silicide materials caused by silicon (Si) contained in the SiN film 9A, which resultantly prevents the electrodes, 6 and 7, from increasing resistivity thereof.

The HEMTs and the processes of forming the HEMTs are not restricted to those described above, and various changes and modifications be apparent for those in an ordinary person in the field. For instance, the SiN film, 9 or 9A described above may be replaced to silicon-oxy-nitride (SiOₓN_{y}) film having bandgap energy smaller than that of AlO film, 10 or 10A, where compositions of oxygen and nitrogen satisfy relations of 0<x<=1 and 0<y<=1.

Also, the AlO film, 10 or 10A, may be replaced to another film having bandgap energy greater than that of the SiN film, 9 or 9A. For instance, a film made of aluminum nitride (AlN), silicon oxide (SiO), or aluminum-oxy-nitride (AlON) may be replaced to the AlO film, 10 or 10A, where the AlNx film satisfies a relation of 1<=x<2, the SiOx film satisfies a relation of 2<=x<=4, and the AlOxNy film satisfies relations of 1<=x<=4 and 1/2<=y<=1, respectively. That is, the AlO film 10 may be replaced to at least one of AlN, SiO, and AlON each having nitride or oxygen rich composition.

Also, the cleaning of the SiN film, 9 or 9A, by an organic solvent and the first introduction of an oxidizer for aluminum (Al) into a chamber for forming the AlO film, 10 or 10A, are unnecessary to be doubly carried out. At least one of the cleaning by an organic solvent and the introduction of an oxidizer into the chamber is necessary to be carried out. Also, the cap layer 5 is sometimes unnecessary to be formed on the barrier layer 4. In such a case, the SiN film, 9 or 9A, is directly in contact to the barrier layer 4.

The present invention is further specifically described as referring to the following embodiment; but the invention is not restricted to those embodiment.

The process sequentially grows, by the OMVPE technique, a GaN layer, which operates as the channel layer, by a thickness of 3000 nm; an n-type AlGaN layer, which operates as the barrier layer, by a thickness of 20 nm, and an i-type GaN layer, which operates as the cap layer, by a thickness of 2 nm. Then, the process forms the SiN film on the cap layer by a thickness of 20 nm by the CVD technique, where the SiN film has the composition ratio of nitrogen (N) to silicon (Si) is equal to 2/3, namely N/Si=2/3. Then, the process forms on the SiN film the AlO film by a thickness of 40 nm, where the AlO film has the composition ratio of oxygen (O) against aluminum (Al) is equal to 3/2, namely O/Al=3/2. After the formation of the openings in the SiN film and the AlO film, the source and drain electrodes made of stacked metals of titanium (Ti), aluminum (Al), and gold (Au) are formed within the openings, while, the gate electrode made of stacked metals of nickel (Ni) and gold (Au) is formed within another openings so as to be direct contact to the cap layer. Thus, the HEMT of the embodiment having the cross section shown in FIG. 1 is formed.

Another HEMT, which provides no AlO film on the SiN film but other arrangements are substantially same with those of the HEMT 1, is also prepared for evaluating the current collapsing of the HEMT, where the cross section of the other HEMT is shown in FIG. 4.

Evaluation of Current Collapse

Variation of the drain current was first evaluated as varying the drain bias. Specifically, providing a fixed gate bias Vgs of 2V and varying the drain bias Vds to 10 V, the drain current Id was measured. Then, a pulsed stress was applied to the HEMT. Specifically, the drain bias Vds of 10 V was applied as fixing the gate bias Vgs of −5V. Because of a large negative gate bias Vgs, substantially no drain current flowed in the HEMT. Subsequently, the variation of the drain current Id was measured again as applying a positive gate bias Vgs of 2 V. Decrement of the drain current Id after the pulsed stress was applied from those before the pulsed stress was compared for the HEMT of the present invention with the conventional HEMT.

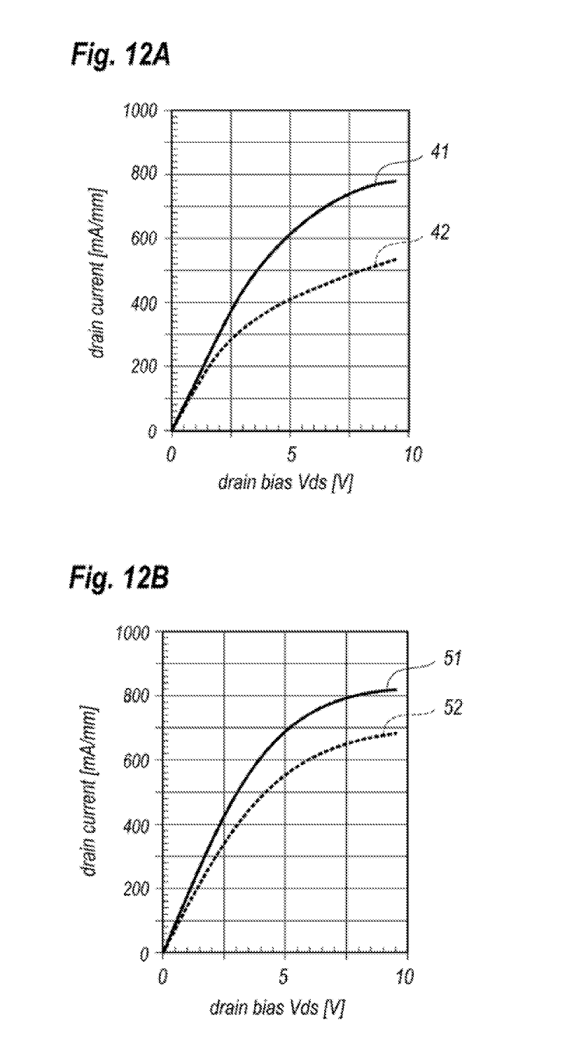

FIG. 12A shows the decrement of the drain current Id after the pulsed stress was applied for the conventional HEMT with no AlO film on the SiN film; while, FIG. 12B shows the result of the HEMT of the invention which has an AlO film on the SiN film. In FIGS. 12A and 12B, solid lines, 41 and 51, correspond the drain currents measured before the pulsed stress; while, dotted lines, 42 and 52, correspond to the drain currents after the pulsed stress. As FIGS. 12 A and 12B explicitly indicate, the conventional HEMT in FIG. 12A shows a larger decrease in the drain current compared with the HEMT Of the present invention shown in FIG. 12B. For instance, the drain current Id at the drain bias Vds of 5 V after the pulsed stress decreases to 60% of that before the pulsed stress in the conventional HEMT; while, the HEMT of the present embodiment shows the decrease of the drain current Id after the pulsed stress only by 80% of that before the pulsed stress. Thus, the HEMT of the present embodiment effectively suppresses the current collapse, which seems to be existence of the AlO film on the SiN film.

While particular embodiments of the present invention have been described herein for purposes of illustration, many modifications and changes will become apparent to those skilled in the art. Accordingly, the appended claims are intended to encompass all such modifications and changes as fall within the true spirit and scope of this invention.

The present application claims the benefit of priority of Japanese Patent Application No. 2015-221376, filed on Nov. 11, 2015, which is incorporated herein by reference.

I claim:

1. A high electron-mobility transistor (HEMT), comprising:
a channel layer made of nitride semiconductor materials;
a barrier layer provided on the channel layer, the barrier layer being made of nitride semiconductor materials having electron affinity smaller than electron affinity of the channel layer;
a first insulating film provided on the barrier layer, the first insulating film being made of one of silicon nitride (SiN) and silicon oxy-nitride (SiON) with a thickness not thinner than 10 nm but not thicker than 50 nm; and
a second insulating film provided on the first insulating film, the second insulating film being made of one of aluminum oxide (AlO), aluminum nitride (AlN), silicon oxide (SiO), aluminum oxy-nitride (AlON) with a thickness not thinner than 20 nm but not thicker than 100 nm.

2. The HEMT of claim 1,
wherein the first insulating film is made of silicon nitride (SiN) with a silicon rich composition compared with an ordinary silicon nitride having the composition of Si₃N₄.

3. The HEMT of claim 2,
wherein the first insulating film made of SixNy has a composition ratio (y/x) of nitrogen against silicon greater than or equal to 3/17 but smaller than or equal to 4/3.

4. The HEMT of claim 1,
wherein the first insulating film is made of SiON with a silicon rich composition compared with an ordinary silicon oxy-nitride having a composition of Si₃(ON)₄.

5. The HEMT of claim 4,
wherein the first insulating film made of Six(ON)y has a composition ration (y/x) of oxy-nitrogen against silicon greater than or equal to 3/17 but smaller than or equal to 4/3.

6. The HEMT of claim 1,
wherein the second insulating film made of AlO and SiO with oxygen rich composition compared with an ordinary aluminum oxide having a composition of Al₂O₃ and an ordinary silicon oxide having a composition of SiO₂.

7. The HEMT of claim 6,
wherein the second insulating film made of aluminum oxide (AlxOy) has a composition ratio (y/x) of oxygen against aluminum greater than 3/2 but smaller than or equal to 3

8. The HEMT of claim 6,
wherein the second insulating film made of silicon oxide (SiOx) has a composition of oxygen greater than 2 but smaller than 4.

9. The HEMT of claim 1,
wherein the second insulating film made of AlNx with nitrogen rich composition compared with an ordinary aluminum nitride having a composition of AlN.

10. The HEMT of claim 9,
wherein the second insulating film made of AlNx has a nitrogen composition greater than 1 but smaller than 2.

11. The HEMT of claim 1,
wherein the second insulating film made of AlON has a composition of oxygen greater than or equal to 1 but smaller than or equal to 4, and a composition of nitrogen greater than or equal to 0.5 but smaller than or equal to 1.

12. The HEMT of claim 1,
further comprising a cap layer between the barrier layer and the first insulating film, the cap layer being made of nitride semiconductor material.

13. The HEMT of claim 1,
further comprising:
a source electrode, a drain electrode, and a gate electrode, each provided on the barrier layer, the gate electrode being positioned between the source electrode and the drain electrode, and
a third insulating film that covers the source electrode, the gate electrode, the drain electrode, and the second insulating film exposed between the source electrode and the gate electrode, and between the drain electrode and the gate electrode.

14. The HEMT of claim 13,
wherein the first insulating film forms a gap against the source electrode and another gap against the drain electrode, the second insulating film partially filling the gap and the another gap.

15. A high electron-mobility transistor (HEMT), comprising:
a channel layer made of nitride semiconductor material;
a barrier layer provided on the channel layer, the barrier layer being made of nitride semiconductor materials having electron affinity greater than electron affinity of the channel layer;
a first insulating film provided on the barrier layer, the first insulating film being made of silicon nitride (SiN) with a silicon rich composition compared with an ordinary silicon nitride with a composition of Si₃N₄; and
a second insulating film provided on the first insulating film, the second insulating film being made of aluminum oxide (AlO) with an aluminum rich composition compared with an ordinary aluminum oxide with a composition of Al₂O₃.

16. The HEMT of claim 15,
wherein the first insulating film made of SixNy has a composition ratio (y/x) of nitrogen against silicon not less than 3/17 but not greater than 4/3, and
wherein the second insulating film made of AluOv has a composition ratio (v/u) of oxygen against aluminum not less than 3/2 but not greater than 3.

17. The HEMT of claim 15,
further including,
a cap layer between the barrier layer and the first insulating film, and
a source electrode, a drain electrode, and agate electrode provided on the cap layer through the first insulating film and the second insulating film,
wherein the first insulating film forms a gap against the source electrode and another gap against the drain electrode, the second insulating film partially filling the gap and the another gap.
